(19) United States
(12) Patent Application Publication
(10) Pub. No.: US 2025/0157834 A1
(43) Pub. Date: May 15, 2025

(54) HIGH-PRESSURE HEAT TREATMENT APPARATUS AND GAS MONITORING MODULE USED THEREFOR

(71) Applicant: HPSP Co., Ltd., Hwaseong-si, Gyeonggi-do (KR)

(72) Inventor: Kun Young LIM, Uiwang-si, Gyeonggi-do (KR)

(73) Assignee: HPSP Co., Ltd., Hwaseong-si, Gyeonggi-do (KR)

(21) Appl. No.: 18/723,082

(22) PCT Filed: Dec. 20, 2022
(86) PCT No.: PCT/KR2022/020873

§ 371 Date: Jun. 21, 2024

(30) Foreign Application Priority Data
Dec. 23, 2021 (KR) 10-2021-0185712

(51) Int. Cl. H01L 21/67

(52) U.S. Cl. CPC H01L 21/67109; H01L 21/67017; H01L 21/67253

(57) ABSTRACT

The present invention provides a high-pressure heat treatment apparatus and a gas monitoring module used therefor, the high-pressure heat treatment apparatus comprising: an inner chamber formed to accommodate an object for heat treatment; an outer chamber having a first part and a second part disposed to face each other to define an accommodation space, and an inner O-ring and an outer O-ring disposed in a corresponding region between the first part and the second part, wherein the accommodation space accommodates the inner chamber; an air supply module configured to supply a reaction gas for the heat treatment to the inner chamber at a first pressure higher than atmospheric pressure, and to supply a protective gas to the outer chamber at a second pressure set in relation to the first pressure; a monitoring module having a buffer channel positioned between the inner O-ring and the outer O-ring and supplied with a buffer gas at a third pressure, and a sensing unit configured to sense an environment related to the buffer gas; and a control module configured to determine whether an internal leak of a gas flowing from the accommodation space to the buffer channel via the inner O-ring occurs, on the basis of a result of sensing the environment related to the buffer gas.

### TECHNICAL FIELD

The present invention relates to a high-pressure heat treatment apparatus used to heat treat an object in a high pressure environment and a gas monitoring module used therefor.

### BACKGROUND ART

In general, an ion implantation process during semiconductor fabrication may cause damage to an interface of a wafer. Annealing may be a process of treating the damage to the wafer through heat treatment. In addition to the annealing, the heat treatment may also be performed on the wafer when activating impurities, when performing a chemical vapor deposition (CVD) process to form a thin film, and when performing an ohmic contact alloy process.

During the heat treatment, gas may act on the wafer. The gas may be supplied at a high pressure to a chamber accommodating the wafer. After the heat treatment is finished, the used gas may be exhausted from the chamber. After the gas is exhausted, the heat-treated wafer may be withdrawn from the chamber. A new wafer and gas may then be provided to the chamber for the next heat treatment.

The chamber may be required to have a sealing force of a certain level or above to prevent the supplied gas from leaking to the outside. As the heat treatment process is continuously performed, the sealing force of the chamber may be weakened. Due to the weakened sealing force, gas in the chamber may leak to the outside. This issue may cause a decrease in heat treatment efficiency.

### DISCLOSURE

### Technical Problem

An object of the present invention is to provide a high-pressure heat treatment apparatus which may detect an internal gas leak occurring in a chamber to prevent its final external leak in advance, and a gas monitoring module used therefor.

### Technical Solution

According to an embodiment of the present invention, provided is a high-pressure heat treatment apparatus, the apparatus including: an inner chamber accommodating an object for heat treatment; an outer chamber having a first part and a second part facing each other to define an accommodation space accommodating the inner chamber, and an inner O-ring and an outer O-ring disposed in a corresponding region of the first part and the second part; a gas supply module configured to supply a reaction gas for the heat treatment to the inner chamber at a first pressure higher than atmospheric pressure, and supply a protective gas to the outer chamber at a second pressure set in relation to the first pressure; a monitoring module having a buffer channel, which is positioned between the inner O-ring and the outer O-ring and to which a buffer gas is supplied at a third pressure, and a sensing unit configured to sense an environment related to the buffer gas; and a control module configured to determine whether an internal leak of a gas flowing from the accommodation space to the buffer channel by passing through the inner O-ring occurs, on the basis of a result of sensing the environment related to the buffer gas.

The monitoring module may further include a buffer gas supply line connected to the gas supply module and be configured to supply the buffer gas to the buffer channel.

The apparatus may further include a gas exhaust module configured to exhaust the reaction gas or the protective gas from the inner chamber or the outer chamber, wherein the monitoring module further includes a buffer gas exhaust line connected to the gas exhaust module and configured to exhaust the buffer gas from the buffer channel.

The buffer gas exhaust line may be connected to the buffer gas supply line, and the monitoring module may further include a buffer gas supply valve for regulating the buffer gas supply line, and a buffer gas exhaust valve for regulating the buffer gas exhaust line.

The sensing unit may include a pressure sensing device connected to one of the buffer gas supply line and the buffer gas exhaust line, and configured to sense a pressure change in the buffer gas in a state where the buffer gas supply valve and the buffer gas exhaust valve are closed.

The buffer gas exhaust line may be formed independently of the buffer gas supply line, and the sensing unit may include a gas sensing device installed at the buffer gas exhaust line and be configured to sense the reaction gas mixed in the buffer gas.

The monitoring module may further include a pressure adjustment unit disposed upstream of the gas sensing device, and lowering a pressure of a flow flowing into the gas sensing device to a reference pressure or below.

The buffer channel may be formed concavely in at least one of the first part and the second part.

The third pressure may be set to be lower than the second pressure.

The buffer channel may have a ring shape and extend in a circumferential direction of the inner O-ring or the outer O-ring.

The control module may control the monitoring module and the gas exhaust module to exhaust the reaction gas, the protective gas, and the buffer gas when determining that a gas leak occurs.

According to another embodiment of the present invention, provided is a gas monitoring module for a high-pressure heat treatment apparatus, the module including: a buffer channel positioned between an inner O-ring and an outer O-ring, the inner O-ring and the outer O-ring being disposed in a corresponding region of a first part and a second part, and the first part and the second part facing each other to define an accommodation space where a processing gas is supplied at a pressure higher than atmospheric pressure; a buffer gas supply line connected to the buffer channel and configured to supply a buffer gas to the buffer channel at a lower pressure than the processing gas; a buffer gas exhaust line connected to the buffer channel and configured to exhaust the buffer gas from the buffer channel; and a sensing unit configured to sense an environment related to the buffer gas when an internal leak of the processing gas into the buffer channel occurs as the processing gas passes through the inner O-ring.

The buffer channel may have a ring shape and extends in a circumferential direction of the inner O-ring or the outer O-ring.

The sensing unit may include a pressure sensing device sensing an increased pressure of the buffer gas, caused by the internal leak.

The module may further include: a buffer gas supply valve for regulating the buffer gas supply line; and a buffer gas exhaust valve for regulating the buffer gas exhaust line, wherein the pressure sensing device is configured to sense the pressure of the buffer gas in a state where the buffer gas supply valve and the buffer gas exhaust valve are closed.

### Advantageous Effects

According to the high-pressure heat treatment apparatus and a gas monitoring module used therefor according to the present invention configured as above, the inner O-ring and the outer O-ring may be installed in the corresponding region of the first and second parts of the chamber, and the buffer channel, to which the buffer gas is supplied, may be positioned between the O-rings. In this state, when the sensing unit senses the environment related to the buffer gas, the control module may determine whether the internal leak of the gas flowing to the buffer channel via the inner O-ring occurs based thereon. In this way, it is possible to detect the leakage issue before the gas in the chamber leaks to the outside.

Furthermore, it is possible to prevent the external gas leakage in advance when the control module exhausts the gas in the chamber and the buffer gas.

### DESCRIPTION OF DRAWINGS

FIG. 1 is a conceptual diagram of a high-pressure heat treatment apparatus 100 according to an embodiment of the present invention.

FIG. 2 is a block diagram for explaining a control configuration of the high-pressure heat treatment apparatus 100 in FIG. 1.

FIG. 3 is a partial cross-sectional view more specifically showing components related to a monitoring module 150 of the high-pressure heat treatment apparatus 100 in FIG. 1.

FIG. 4 is a conceptual diagram for explaining an operation method of the monitoring module 150 in FIG. 3.

FIG. 5 is a conceptual diagram for explaining an operation method of a monitoring module 150′ according to a modified example of the monitoring module 150 in FIG. 4.

FIG. 6 is a flowchart for explaining a gas leak response method of the high-pressure heat treatment apparatus 100 according to another embodiment of the present invention.

### BEST MODE

Hereinafter, a high-pressure heat treatment apparatus and a gas monitoring module used therefor according to embodiments of the present invention are described in detail with reference to the accompanying drawings. Throughout the specification, components that are the same as or similar to each other are denoted by reference numerals that are the same as or similar to each other even in a different embodiment, and a description thereof is replaced by the first description.

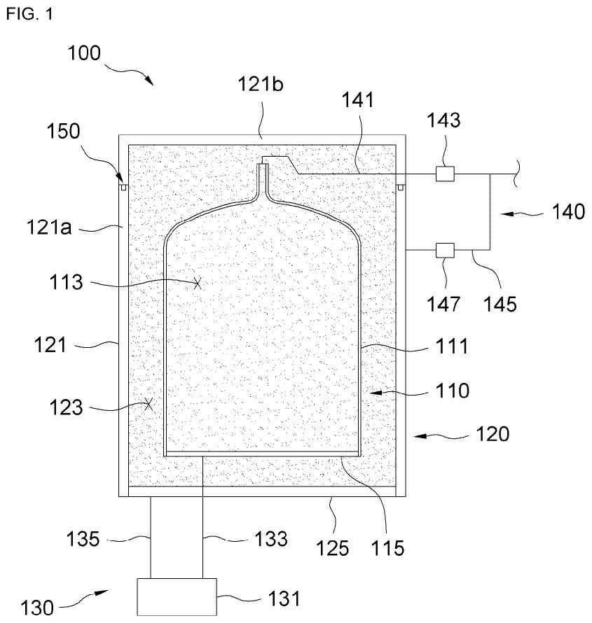

FIG. 1 is a conceptual diagram of a high-pressure heat treatment apparatus 100 according to an embodiment of the present invention.

Referring to this drawing, the high-pressure heat treatment apparatus 100 may include an inner chamber 110, an outer chamber 120, a gas supply module 130, a gas exhaust module 140, and a monitoring module 150.

The inner chamber 110 may have a hollow housing 111. An accommodation space 113 of the housing 111 may accommodate an object for heat treatment. The housing 111 may be made of a non-metallic material, for example, quartz, to reduce a possibility that contaminants (particles) occur in a high-temperature and high-pressure environment. A door 115 for opening and closing the accommodation space 113 may be disposed at a lower end of the housing 111. As the door 115 descends, the accommodation space 113 may be opened, and the object may be input into the accommodation space 113 while being mounted on a holder (not shown). As a heater (not shown) disposed outside the inner chamber 110 is operated, a temperature of the accommodation space 113 may reach several hundred degrees Celsius. The object may be, for example, a semiconductor wafer. In this case, the holder may be a wafer boat capable of stacking the semiconductor wafers in a plurality of layers.

The outer chamber 120 may be configured to accommodate the inner chamber 110. Unlike the inner chamber 110, the outer chamber 120 is free from a problem of contamination of the semiconductor wafer, and may thus be made of a metal material. In detail, the outer chamber 120 may have a hollow housing 121. An accommodation space 123 of the housing 121 may accommodate the inner chamber 110. The housing 121 may include a body part 121a and a cover part 121b which are coupled to define the accommodation space 123. The outer chamber 120 may also have a door 125, and the door 125 may descend together with the door 115 to thus open the accommodation space 123.

The gas supply module 130 may be configured to supply a gas to the chamber 110 or 120. The gas supply module 130 may have a gas supplier 131 communicating with a utility (or gas supply facility) of a semiconductor factory. The gas supplier 131 may selectively provide the inner chamber 110 with a reaction gas such as hydrogen/deuterium, fluorine, ammonia, chlorine, or nitrogen. The gas supplier 131 may provide the outer chamber 120 with, a protective gas such as nitrogen which is an inert gas. These reaction gas and protective gas may be collectively referred to as a processing gas. The processing gas may be input to the inner chamber 110 or the outer chamber 120 through a reaction gas line 133 or a protective gas line 135. In detail, the protective gas injected into the outer chamber 120 may be supplied to a space between the outer chamber 120 and the inner chamber 110.

The processing gas may have a pressure higher than atmospheric pressure, and may be supplied at a high pressure, for example, from several atmospheres to tens of atmospheres. When a pressure of the reaction gas is a first pressure, and a pressure of the protective gas is a second pressure, these pressures may maintain a predetermined relationship. For example, the second pressure may be set to be slightly higher than the first pressure. Such a pressure difference may prevent the reaction gas from leaking from the inner chamber 110.

The gas exhaust module 140 may be configured to exhaust the processing gas from the chamber 110 or 120. In order to exhaust the reaction gas from the inner chamber 110, a gas exhaust pipe 141 may be connected to the top of the inner chamber 110 and externally extend from the outer chamber 120. A gas discharger 143 may be installed at the gas exhaust pipe 141. The gas discharger 143 may be a valve that regulates the exhaust of the reaction gas.

A gas exhaust pipe 145 communicating with the outer chamber 120 and a gas discharger 147 installed thereat may be provided also to discharge the protective gas from the outer chamber 120. These gas exhaust pipes 141 and 145 may communicate with each other. Accordingly, the reaction gas may be diluted in the protective gas and exhausted while having a lower concentration.

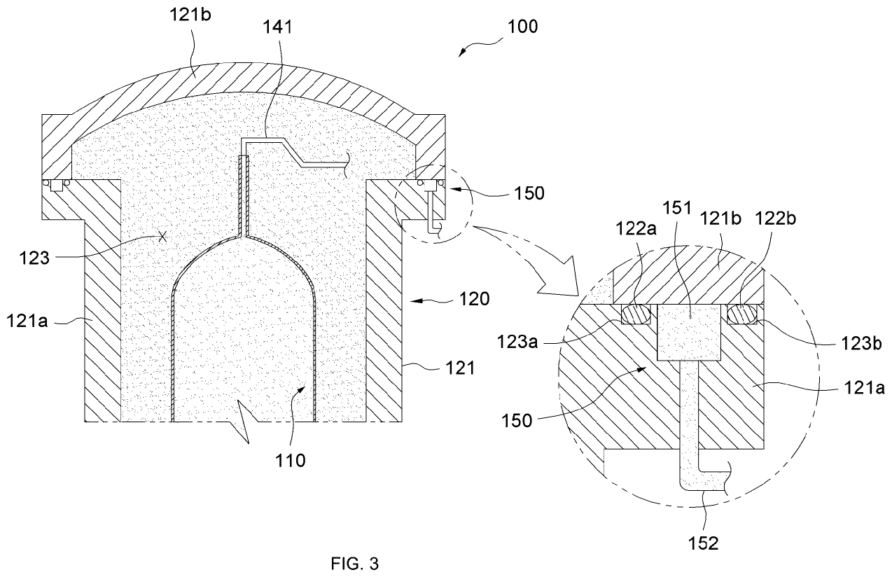

The monitoring module 150 may be configured to detect whether the processing gas leaks through the outer chamber 120. In detail, the processing gas may leak to the outside through a coupled portion of the outer chamber 120. The coupled portion may be, for example, a portion where the body part 121a and the cover part 121b are coupled with each other, or where the housing 121 and the door 125 are coupled with each other. An O-ring may be disposed at the coupled portion to increase a sealing force. However, leakage may occur through the O-ring when the O-ring is damaged. The monitoring module 150 may also be referred to as a gas monitoring module because this module monitors the gas leak. A specific configuration of the (gas) monitoring module 150 is described below with reference to FIG. 3 or the like.

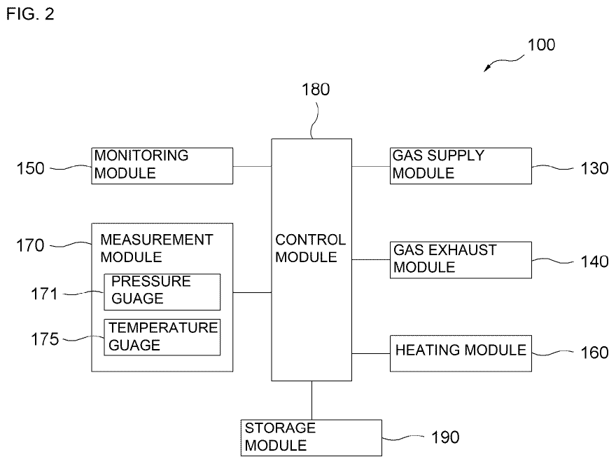

The description describes a control configuration of the high-pressure heat treatment apparatus 100 with reference to FIG. 2. FIG. 2 is a block diagram for explaining the control configuration of the high-pressure heat treatment apparatus 100 in FIG. 1.

Referring to this drawing (and FIG. 1), the high-pressure heat treatment apparatus 100 may further include a heating module 160, a measurement module 170, a control module 180, and a storage module 190 in addition to the gas supply module 130 described above.

The heating module 160 may include the above-mentioned heater. The heater may be disposed in the accommodation space 123 of the outer chamber 120. The heater may heat the reaction gas to a reaction temperature.

The measurement module 170 may be configured to measure an environment of the chamber 110 or 120. The measurement module 170 may include a pressure gauge 171 and a temperature gauge 175. The pressure gauge 171 and the temperature gauge 175 may be installed in each of the chambers 110 and 120.

The control module 180 may be configured to control the gas supply module 130, the gas exhaust module 140, or the like. The control module 180 may control the gas supply module 130 or the like on the basis of a sensing/measurement result of the monitoring module 150 or the measurement module 170.

The storage module 190 may be configured to store data, programs, or the like that the control module 180 may refer to for its control operation. The storage module 190 may include at least one type of storage medium among a flash memory, a hard disk, a magnetic disk, and an optical disk.

Through this configuration, the control module 180 may control an operation of the gas supply module 130 based on a pressure in the chamber 110 or 120 that is acquired through the pressure gauge 171. The processing gas may be injected into the chamber 110 or 120 to reach the first pressure or the second pressure based on the operation of the gas supply module 130.

The control module 180 may also control an operation of the heating module 160 based on a temperature of the chamber 110 or 120 acquired through the temperature gauge 175. The reaction gas in the inner chamber 110 may reach the reaction temperature based on the operation of the heating module 160.

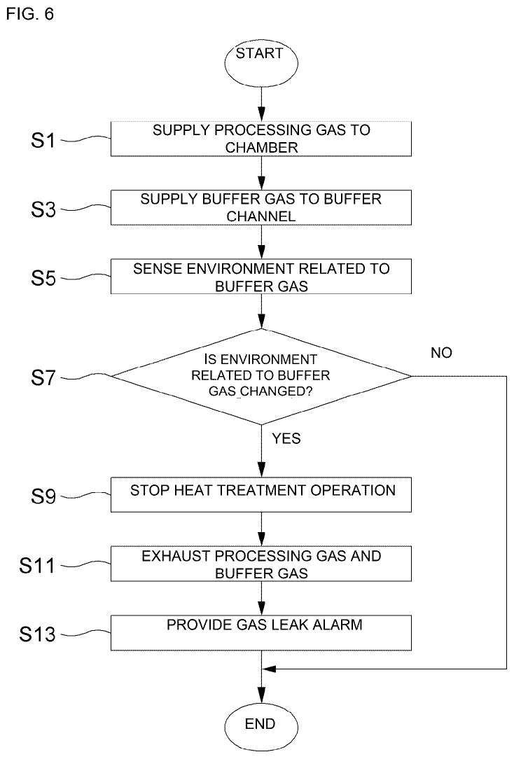

While a heat treatment operation is in progress, the control module 180 may determine that the processing gas internally leaks on the basis of the sensing result of the monitoring module 150. In this case, the control module 180 may stop the heat treatment operation. This configuration is described in detail with reference to FIG. 6.

The description describes the specific configuration and operation of the monitoring module 150 with reference to FIGS. 3 to 6.

FIG. 3 is a partial cross-sectional view more specifically showing components related to the monitoring module 150 of the high-pressure heat treatment apparatus 100 in FIG. 1.

Referring further to this drawing, the housing 121 may include the body part 121a and the cover part 121b. The body part 121a may have a substantially cylindrical shape, and the cover part 121b may have a shape corresponding to an open top of the body part 121a. The cover part 121b may have a substantially dome shape. The body part 121a and the cover part 121b may be coupled to each other to define the accommodation space 123. These parts may respectively be referred to as a first part and a second part.

Some of the first part 121a and the second part 121b may face each other and be in contact with each other. This portion where these parts are in contact with each other may be referred to as a corresponding region of the parts. An inner O-ring 122a and an outer O-ring 122b may be disposed in the corresponding region. The inner O-ring 122a may be closer to the accommodation space 123 than the outer O-ring 122b. The inner O-ring 122a and the outer O-ring 122b may respectively be seated in an inner groove 123a and an outer groove 123b. The inner groove 123a and/or the outer groove 123b may be concavely formed in the first part 121a and/or the second part 121b.

The monitoring module 150 may be operated in conjunction with the inner O-ring 122a and the outer O-ring 122b. In detail, the monitoring module 150 may have a buffer channel 151 positioned between the inner O-ring 122a and the outer O-ring 122b. The buffer channel 151 may be a space where a buffer gas is supplied at a third pressure. The buffer gas may be an inert gas and may be, for example, the nitrogen gas. The third pressure may be set to be lower than the second pressure. This setting is to prevent the buffer gas from permeating into the accommodation space 123 by passing through the inner O-ring 122a.

The buffer channel 151 may be concavely formed in the first part 121a and/or the second part 121b. The buffer channel 151 may extend in a circumferential direction of the inner O-ring 122a (or the outer O-ring 122b). The buffer channel 151 may have a ring shape when extending to an entire angular section in the circumferential direction of the inner O-ring 122a. On the other hand, the buffer channel 151 may exist only in some angular sections in the circumferential direction of the inner O-ring 122a, or may exist while divided into multiple pieces.

A buffer gas supply line 152 may be connected to the buffer channel 151 to supply the buffer gas to the buffer channel 151. The buffer gas supply line 152 may also be connected to the gas supply module 130, and may receive the buffer gas from the gas supply module 130 to supply the same to the buffer channel 151.

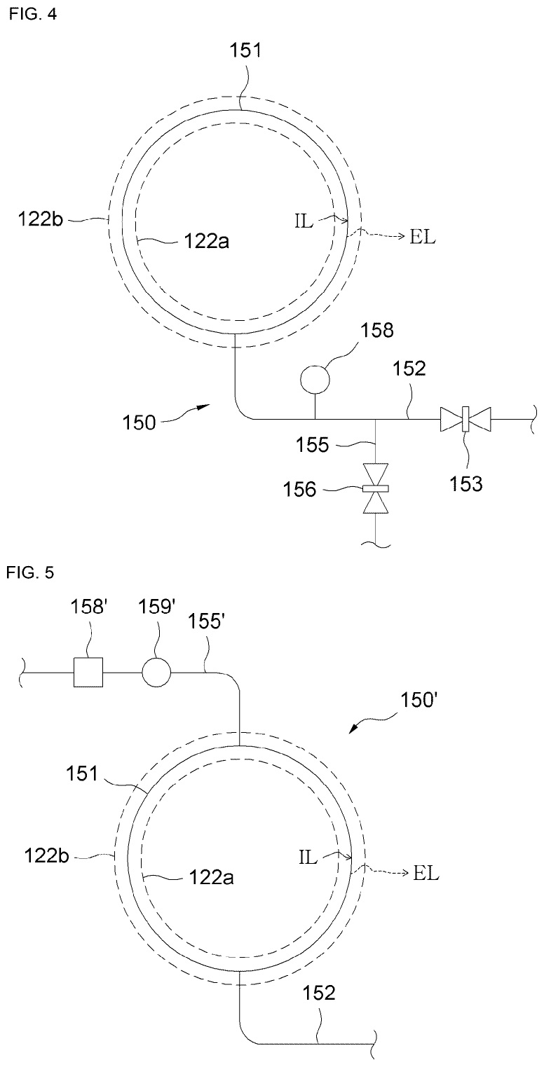

An environment related to the buffer gas in the buffer channel 151 may be sensed by a sensing unit (for example, a sensing unit 158 (see FIG. 4)). The environment may be changed in a case of mixing the reaction gas with the buffer gas, a resultant pressure increase in the buffer gas (in detail, a mixture gas of the buffer gas and the processing gas), or the like. This environmental change may occur when an internal leak (IL) of the processing gas in the accommodation space 123 into the buffer channel 151 occurs as the processing gas passes through the inner O-ring 122a (see FIG. 4). The internal leak (IL) may typically occur when the inner O-ring 122a is damaged.

Even when a sensing result of the sensing unit corresponds to the environmental change, the processing gas may not externally leak from the outer chamber 120. The reason is that the outer O-ring 122b, which exists outside the buffer channel 151, prevents external leakage (EL, see FIG. 4) of the gas. Therefore, detecting the environmental change may provide an important opportunity to prevent an external leak (EL) of the processing gas in advance.

FIG. 4 is a conceptual diagram for explaining an operation method of the monitoring module 150 in FIG. 3.

Referring further to this drawing, the monitoring module 150 may include a buffer gas exhaust line 155 for exhausting the buffer gas from the buffer channel 151. The buffer gas exhaust line 155 may be connected to the gas exhaust module 140 (see FIG. 1), thus allowing the buffer gas to be exhausted through the gas exhaust module 140.

The buffer gas exhaust line 155 may also be connected to the buffer gas supply line 152. Accordingly, a portion of the buffer gas exhaust line 155 that is close to the buffer channel 151 may share a portion of the buffer gas supply line 152. A buffer gas supply valve 153 and a buffer gas exhaust valve 156 may respectively be installed at distinct portions of the buffer gas supply line 152 and the buffer gas exhaust line 155. The buffer supply valve 153 may regulate the supply of the buffer gas through the buffer gas supply line 152. Similarly, the buffer exhaust valve 156 may regulate the exhaust of the buffer gas through the buffer gas exhaust line 155.

The sensing unit 158 may be installed at the shared portion of the buffer gas supply line 152 and the buffer gas exhaust line 155. The sensing unit 158 may be a pressure sensing device sensing a pressure of the buffer gas in the buffer channel 151. The pressure sensing device may sense the pressure of the buffer gas in a state where the buffer supply valve 153 and the buffer exhaust valve 156 are closed. The pressure sensing device may sense a pressure higher than the third pressure when the processing gas leaks (IL) into the buffer channel 151 through the inner O-ring 122a.

Unlike the description provided above, the pressure sensing device may be installed at a portion of the buffer gas supply line 152 that is distinct from the buffer gas exhaust line 155, or vice versa. The pressure sensing device may directly communicate with the buffer channel 151 independently of the buffer gas supply line 152 or the buffer gas exhaust line 155, and may sense a pressure change in the buffer gas.

A gas leak monitoring method different from the above is described with reference to FIG. 5. FIG. 5 is a conceptual diagram for explaining an operation method of a monitoring module 150′ according to a modified example of the monitoring module 150 in FIG. 4.

Referring further to this drawing, a buffer gas exhaust line 155′ of the monitoring module 150′ may be formed independently of the buffer gas supply line 152. Accordingly, these lines may be connected to the buffer channel 151 at different points.

A sensing unit 158′ may be a gas sensing device sensing the reaction gas. To effectively sense the reaction gas, the gas sensing device may be installed at the buffer gas exhaust line 155′. The reaction gas may flow into the buffer channel 151 due to the internal leak (IL) to be mixed into the buffer gas.

The gas sensing device may include a sensitive part which may be damaged by a high pressure of the mixture gas. To prevent this damage, a pressure adjustment unit 159′ may be installed upstream of the gas sensing device. The pressure control unit 159′ may lower a pressure of a flow flowing into the gas sensing device to a reference pressure or below. The reference pressure may be set to a level for protecting the gas sensing device.

The description describes a gas leak response method of the control module 180 with reference to FIG. 6, on the basis of a monitoring result of the monitoring module 150 or 150′ described above. FIG. 6 is a flowchart for explaining a gas leak response method of the high-pressure heat treatment apparatus 100 according to another embodiment of the present invention.

Referring to this drawing (and FIGS. 1 through 5), the control module 180 may control the gas supply module 130 to supply the processing gas to the chamber 110 or 120 in order to perform the heat treatment operation (S1).

The control module 180 may also control the monitoring module 150 or 150′ to supply the buffer gas to the buffer channel 151 (S3). The buffer gas may be supplied through the buffer gas supply line 152.

The monitoring module 150 or 150′ may sense the environment related to the buffer gas, in the buffer channel 151 under the control of the control module 180 (S5). As the processing gas passes through the inner O-ring 122a and flows into the buffer channel 151 (that is, the internal leak (IL) occurs), the sensing unit 158 may sense the increased pressure of the mixture gas, and the sensing unit 158′ may sense the reaction gas.

The control module 180 may stop the heat treatment operation (S9) when determining that the internal leak (IL) occurs, on the basis of a result of sensing the environment (S7). The reason is that continuing the heat treatment operation may be dangerous due to an increased possibility of the external leak (EL) of the processing gas.

The control module 180 may also exhaust the processing gas and the buffer gas (S11). For this purpose, the control module 180 may control the gas exhaust module 140 and the monitoring module 150 or 150′. The reason is to eliminate a risk of the external gas leak (EL) by exhausting all the gas present in the chamber 110 or 120.

The control module 180 may also provide a gas leak alarm (S13). The alarm may be notified to a manager through visual and auditory means. Accordingly, the manager may detect a cause of the internal gas leak (IL) and take a necessary response, for example, replacement of the inner O-ring 122a. In this case, it is possible to completely resolve a gas leak issue.

The high-pressure heat treatment apparatus and the gas monitoring module used therefor as described above are not limited to the configurations and operation methods in the embodiments described above. The embodiments described above may be variously modified by selective combinations of all or some of the respective embodiments.

The monitoring module 150 is described as being installed in the outer chamber 120. However, the monitoring module 150 may be installed in the inner chamber 110. The monitoring module installed in the inner chamber 110 may be configured substantially the same as the monitoring module 150 installed in the outer chamber 120.

### INDUSTRIAL APPLICABILITY

The present invention has potential industrial application in a field of manufacturing a high-pressure heat treatment apparatus and a gas monitoring module used therefor.

1. A high-pressure heat treatment apparatus, the apparatus comprising:
an inner chamber accommodating an object for heat treatment;
an outer chamber having a first part and a second part facing each other to define an accommodation space accommodating the inner chamber, and an inner O-ring and an outer O-ring disposed in a corresponding region of the first part and the second part;
a gas supply module configured to supply a reaction gas for the heat treatment to the inner chamber at a first pressure higher than atmospheric pressure, and supply a protective gas to the outer chamber at a second pressure set in relation to the first pressure;
a monitoring module having a buffer channel, which is positioned between the inner O-ring and the outer O-ring and to which a buffer gas is supplied at a third pressure, and a sensing unit configured to sense an environment related to the buffer gas; and
a control module configured to determine whether an internal leak of a gas flowing from the accommodation space to the buffer channel by passing through the inner O-ring occurs, on the basis of a result of sensing the environment related to the buffer gas.

2. The apparatus of claim 1, wherein the monitoring module further includes a buffer gas supply line connected to the gas supply module and configured to supply the buffer gas to the buffer channel.

3. The apparatus of claim 2, further comprising a gas exhaust module configured to exhaust the reaction gas or the protective gas from the inner chamber or the outer chamber,
wherein the monitoring module further includes a buffer gas exhaust line connected to the gas exhaust module and configured to exhaust the buffer gas from the buffer channel.

4. The apparatus of claim 3, wherein the buffer gas exhaust line is connected to the buffer gas supply line, and
the monitoring module further includes
a buffer gas supply valve for regulating the buffer gas supply line, and
a buffer gas exhaust valve for regulating the buffer gas exhaust line.

5. The apparatus of claim 4, wherein the sensing unit includes a pressure sensing device connected to one of the buffer gas supply line and the buffer gas exhaust line, and configured to sense a pressure change in the buffer gas in a state where the buffer gas supply valve and the buffer gas exhaust valve are closed.

6. The apparatus of claim 3, wherein the buffer gas exhaust line is formed independently of the buffer gas supply line, and
the sensing unit includes a gas sensing device installed at the buffer gas exhaust line and configured to sense the reaction gas mixed in the buffer gas.

7. The apparatus of claim 6, wherein the monitoring module further includes a pressure adjustment unit disposed upstream of the gas sensing device, and lowering a pressure of a flow flowing into the gas sensing device to a reference pressure or below.

8. The apparatus of claim 1, wherein the buffer channel is formed concavely in at least one of the first part and the second part.

9. The apparatus of claim 1, wherein the buffer channel has a ring shape and extends in a circumferential direction of the inner O-ring or the outer O-ring.

10. The apparatus of claim 1, wherein the third pressure is set to be lower than the second pressure.

11. The apparatus of claim 3, wherein the control module controls the monitoring module and the gas exhaust module to exhaust the reaction gas, the protective gas, and the buffer gas when determining that a gas leak occurs.

12. A gas monitoring module for a high-pressure heat treatment apparatus, the module comprising:
a buffer channel positioned between an inner O-ring and an outer O-ring, the inner O-ring and the outer O-ring being disposed in a corresponding region of a first part and a second part, and the first part and the second part facing each other to define an accommodation space where a processing gas is supplied at a pressure higher than atmospheric pressure;
a buffer gas supply line connected to the buffer channel and configured to supply a buffer gas to the buffer channel at a lower pressure than the processing gas;
a buffer gas exhaust line connected to the buffer channel and configured to exhaust the buffer gas from the buffer channel; and
a sensing unit configured to sense an environment related to the buffer gas when an internal leak of the processing gas into the buffer channel occurs as the processing gas passes through the inner O-ring.

13. The module of claim 12, wherein the buffer channel has a ring shape and extends in a circumferential direction of the inner O-ring or the outer O-ring.

14. The module of claim 12, wherein the sensing unit includes a pressure sensing device sensing an increased pressure of the buffer gas, caused by the internal leak.

15. The module of claim 14, further comprising:
a buffer gas supply valve for regulating the buffer gas supply line; and
a buffer gas exhaust valve for regulating the buffer gas exhaust line,
wherein the pressure sensing device is configured to sense the pressure of the buffer gas in a state where the buffer gas supply valve and the buffer gas exhaust valve are closed.
